(19) United States
(12) Patent Application Publication
(10) Pub. No.: US 2025/0197575 A1
(43) Pub. Date: Jun. 19, 2025

(54) FLUORORESIN FILM, METAL-CLAD LAMINATE AND SUBSTRATE FOR CIRCUIT

(71) Applicant: DAIKIN INDUSTRIES, LTD., Osaka (JP)

(72) Inventors: Mayuko TATEMICHI, Osaka (JP); Nobuyuki Komatsu, Osaka (JP); Tatsuya Higuchi, Osaka (JP); Koji Yokotani, Osaka (JP); Kenzo Takahashi, Osaka (JP); Kentaro Oshima, Osaka (JP)

(73) Assignee: DAIKIN INDUSTRIES, LTD., Osaka (JP)

(21) Appl. No.: 19/020,439

(22) Filed: Jan. 14, 2025

Related U.S. Application Data
(63) Continuation of application No. PCT/JP2023/026943, filed on Jul. 24, 2023.

(30) Foreign Application Priority Data
Jul. 22, 2022 (JP) 2022-117316

(51) Int. Cl. C08J 5/18

(52) U.S. Cl. CPC C08J 5/18; C08J 2327/18

(57) ABSTRACT

Provided are a fluororesin film with excellent bonding to metal foil such as copper foil, and a metal-clad laminate using the same. A fluororesin film that is a film including a fluororesin, where the number of conductive foreign matters that are present in the film and have a length of 50 μm or more in a flow direction or a width direction of the film is less than 60/square meter.

### CROSS REFERENCE TO RELATED APPLICATIONS

This application is a Rule 53(b) Continuation of International Application No. PCT/JP2023/026943 filed Jul. 24, 2023, which claims priority from Japanese Patent Application No. 2022-117316 filed Jul. 22, 2022, the respective disclosures of all of the above are incorporated herein by reference in their entirety.

### TECHNICAL FIELD

The present disclosure relates to a fluororesin film, a metal-clad laminate and a substrate for circuits.

### BACKGROUND ART

In circuit boards, low transmission-loss boards in which disconnection of signal lines is less likely to occur have been required. To this end, there is a general need for films to be bonded to copper foil without deformation. So far, several films that have good appearance without unevenness on the surface have been proposed (Patent Literatures 1 to 3).

Among them, for example, Patent Literature 1 proposes a roll film having an arithmetic average surface roughness of 0.1 μm or less on both sides, in which the winding dislocation with respect to the axial direction of the winding core is 5 mm or less.

In addition, Patent Literature 4 describes that setting the terminal group other than —CF₃ group of a fluorine-containing copolymer used for electric wires to 50 or less per 10⁶ carbon atoms eliminates foaming caused by thermal decomposition during extrusion and can reduce poor forming, and also prevents recombination (cross-linking) between molecules of the fluorine-containing copolymer during extrusion, which causes fisheyes, and can thus reduce the number of fisheyes.

### CITATION LIST

### Patent Literature

Patent Literature 1: Japanese Patent Laid-Open No. 2021-160856
Patent Literature 2: International Publication No. 2017/022575
Patent Literature 3: Japanese Patent Laid-Open No. 2017-119741
Patent Literature 4: International Publication No. 2008/047906

### SUMMARY

The present disclosure is a fluororesin film that is a film comprising a fluororesin, wherein the number of conductive foreign matters that are present in the film and have a length of 50 μm or more in a flow direction or a width direction of the film is less than 60/square meter.

### DESCRIPTION OF EMBODIMENTS

Hereinafter the present disclosure will be described in more detail.

The present disclosure is a film comprising a fluororesin, wherein the number of conductive foreign matters that are present in the surface of the film and have a length of 50 μm or more in a flow direction or a width direction of the film is less than 60/square meter.

In the present description, the flow direction of the film refers to the direction in which the film flows when forming and processing the film using a film production device. The width direction means a direction perpendicular to the flow direction. The forming and processing the film includes a melt forming method such as extrusion, and a casting method in which a solution or a dispersion containing a fluororesin is prepared and then applied to and dried on a substrate.

The present inventors have found that conductive foreign matters are present in a fluororesin film, and in the vicinity of the foreign matters, the thickness of the film greatly varies, and when such a fluororesin film is applied to a circuit board, it causes poor appearance and poor bonding to metal foil.

The present inventors have further found that a film in which the number of the conductive foreign matters that are present in the surface of the film and have a length of 50 μm or more in a flow direction or a width direction of the film is less than 60/square meter can suppress poor appearance and poor bonding to metal foil and can provide a circuit board with low transmission loss.

The fluororesin film of the present disclosure is a film that reduces poor appearance and poor bonding to metal foil, and provides excellent bonding to metal foil.

The present inventors have also confirmed that the conductive foreign matters are metals such as nickel, carbide, and the like. Nickel is mainly derived from a filter in a film melt extruder and the like used in the film production processes. Thus, metals such as nickel in the film can be maximally reduced by using an ultrasonically cleaned, nickel-based metal sintered filter.

It has also been found that carbide is generated by thermal decomposition of unstable functional groups of the fluororesin during extrusion. Thus, reducing the number of unstable functional groups of the fluororesin suppresses the generation of carbide.

The present disclosure will be described in more detail below.

The present disclosure relates to a film comprising a fluororesin. The film may include resin other than fluororesin, rubber, an additive and filler.

Furthermore, the fluororesin may include at least one functional group selected from a carbonyl group-containing group (e.g., an acid anhydride group, a group having a carbonyl group between carbon atoms of a hydrocarbon group, a carbonate group, a carboxyl group, a haloformyl group, and an alkoxy carbonyl group), a hydroxyl group, an epoxy group, an amide group, an amino group and an isocyanate group.

The method for introducing the above functional group is not limited, and the functional group may be introduced into resin when producing fluororesin. In that case, the functional group is derived from at least one selected from the group consisting of a monomer, a chain transfer agent and a polymerization initiator used in production. Examples of monomers above include itaconic anhydride, citraconic anhydride, 5-norbornene-2,3-dicarboxylic anhydride and maleic anhydride. Examples of chain transfer agents include those derived from methanol, acetic acid, acetic anhydride, methyl acetate, ethylene glycol or propylene glycol. Examples of polymerization initiators include ammonium persulfate, potassium persulfate, di-n-propyl peroxydicarbonate, diisopropyl peroxycarbonate, tert-butyl peroxyisopropyl carbonate, bis(4-tert-butylcyclohexyl)peroxy dicarbonate and di-2-ethylhexyl peroxydicarbonate.

A fluororesin which can be melt molded is more preferred as fluororesin. Examples thereof include a tetrafluoroethylene·perfluoroalkyl vinyl ether copolymer (PFA), a copolymer including a chlorotrifluoroethylene (CTFE) unit (CTFE copolymer), a tetrafluoroethylene·hexafluoropropylene copolymer (FEP), a tetrafluoroethylene·ethylene copolymer (ETFE), polychlorotrifluoroethylene (PCTFE), a chlorotrifluoroethylene·ethylene copolymer (ECTFE), polyvinylidene fluoride (PVDF), polyvinyl fluoride (PVF), a tetrafluoroethylene·hexafluoropropylene·vinylidene fluoride copolymer (THV) and a tetrafluoroethylene·vinylidene fluoride copolymer.

Of these fluororesins which can be melt molded, a tetrafluoroethylene·perfluoroalkyl vinyl ether copolymer (PFA) and a tetrafluoroethylene·hexafluoropropylene copolymer (FEP) are preferred.

Use of the above fluororesin which can be melt molded allows melt molding, and thus the cost of processing can be lower than cases using PTFE. Furthermore, adhesiveness when bonding to metal foil can be improved.

It is preferable that the resin constituting the above fluororesin film has a glass transition temperature of 40° C. or more. A glass transition temperature of 40° C. or more is preferred because the resin is less likely to be deformed at the ambient temperature when roll film is stored at room temperature. The resin has a glass transition temperature of more preferably 60° C. or more and further preferably 80° C. or more. The upper limit is not limited, and is preferably 200° C. or less, more preferably 160° C. or less, and further preferably 120° C. or less in view of adhesion.

The above PFA has a melting point of preferably 180 to 340° C., more preferably 230 to 330° C. and further preferably 280 to 320° C. The above melting point corresponds to the local maximum value in a heat-of-fusion curve when temperature is increased at a rate of 10° C./minute using a differential scanning calorimeter (DSC).

The above PFA is not limited, and a copolymer in which the molar ratio between the TFE unit and the PAVE unit (TFE unit/PAVE unit) is 70/30 or more and less than 99.5/0.5 is preferred. The molar ratio is more preferably 70/30 or more and 98.9/1.1 or less, and further preferably 80/20 or more and 98.5/1.5 or less. When the ratio of the TFE unit is very low, mechanical properties tend to be reduced. When the ratio of the TFE unit is very high, the resin has extremely high melting point and moldability tends to be reduced.

The above PFA may be a copolymer consisting of only TFE and PAVE or is preferably a copolymer in which the ratio of the monomer unit derived from a monomer copolymerizable with TFE and PAVE is 0.1 to 10% by mole and the total of the TFE unit and the PAVE unit is 90 to 99.9% by mole. Examples of monomers copolymerizable with TFE and PAVE include HFP, a vinyl monomer represented by CZ₃Z₄═CZ₅(CF₂)ₙZ₆ (in which Z₃, Z₄ and Z₅ are the same or different and represent a hydrogen atom or a fluorine atom, Z₆ represents a hydrogen atom, a fluorine atom or a chlorine atom, and n represents an integer of 2 to 10), and an alkyl perfluorovinyl ether derivative represented by CF₂═CF—OCH₂—Rf₇ (in which Rf₇ represents a perfluoroalkyl group having 1 to 5 carbon atoms). Examples of other copolymerizable monomers include a cyclic hydrocarbon monomer having an acid anhydride group. Examples of acid anhydride monomers include itaconic anhydride, citraconic anhydride, 5-norbornene-2,3-dicarboxylic anhydride and maleic anhydride. One of the acid anhydride monomers may be used alone or two or more of them may be used in combination.

The above FEP is not limited and a copolymer in which the molar ratio between the TFE unit and the HFP unit (TFE unit/HFP unit) is 70/30 or more and less than 99/1 is preferred. The molar ratio is more preferably 70/30 or more and 98.9/1.1 or less, and further preferably 80/20 or more and 97/3 or less. When the ratio of the TFE unit is very low, mechanical properties tend to be reduced. When the ratio of the TFE unit is very high, the resin has extremely high melting point and moldability tends to be reduced. FEP is also preferably a copolymer in which the ratio of the monomer unit derived from a monomer copolymerizable with TFE and HFP is 0.1 to 10% by mole and the total of the TFE unit and the HFP unit is 90 to 99.9% by mole. Examples of monomers copolymerizable with TFE and HFP include an alkyl perfluorovinyl ether derivative. Examples of other copolymerizable monomers include a cyclic hydrocarbon monomer having an acid anhydride group. Examples of acid anhydride monomers include itaconic anhydride, citraconic anhydride, 5-norbornene-2,3-dicarboxylic anhydride and maleic anhydride. One of the acid anhydride monomers may be used alone or two or more of them may be used in combination.

The above FEP has a melting point of preferably 150 to 320° C., more preferably 200 to 300° C. and further preferably 240 to 280° C. The above melting point corresponds to the local maximum value in a heat-of-fusion curve when temperature is increased at a rate of 10° C./minute using a differential scanning calorimeter (DSC).

It is preferable that the number of functional groups in the above fluororesin is small, in particular, the number of unstable functional groups is small. Such fluororesin may be produced by a method in which conditions in production (in polymerization reaction) are adjusted. The number of unstable functional groups is reduced by fluorine gas treatment (fluorination), heat treatment, supercritical gas extraction and the like for fluorine resin after polymerization. Fluorine gas treatment is preferred because it is excellent in processing efficiency and part or all of the unstable functional groups are converted into —CF₃ to form a stable functional group.

The use of such a fluororesin with a reduced number of unstable functional groups can suppress the generation of conductive carbide caused by thermal decomposition of unstable functional groups of the fluororesin during extrusion of film production process. It is also preferable because dielectric loss tangent is reduced and loss of electric signals is reduced.

The number of the unstable functional groups is not limited and is preferably less than 350, more preferably less than 200, further preferably less than 20, and most preferably less than 10 per 1×10⁶ carbon atoms in the main chain of the fluororesin.

With such a range, the generation of carbide during film production is less likely to occur, and the number of conductive foreign matters in the film can be thus reduced.

Specific examples of unstable functional groups include functional groups such as —COF, —COOH free, —COOH bonded, a hydroxyl group (e.g., —CH₂OH), —CONH₂, —COOR (e.g., R═CH₃), —CF₂H and —OCOO—R (e.g., n-propyl carbonate).

The number of unstable functional groups is measured by the following method. First, the above fluororesin is melted and compression-molded to prepare a film having a thickness of 0.25 to 0.3 mm. The film is analyzed by Fourier transform infrared spectrophotometry to obtain an infrared absorption spectrum of the fluororesin, and a differential spectrum relative to a base spectrum of resin which is completely fluorinated and has no functional group is obtained. The number of unstable functional groups per 1×10⁶ carbon atoms in the main chain in the fluororesin is calculated from the peak of absorption of a specific functional group appearing in the differential spectrum based on the following formula (A).

$$N = I \times K / t \qquad ( A )$$

I: Absorbance
K: Coefficient of compensation
t: Thickness of film (mm)

The absorption frequency, molar extinction coefficient and coefficient of compensation for the unstable functional group in the present description will be described in Table 1 for reference. The molar extinction coefficient is determined from the FT-IR data of a model low molecular weight compound.

TABLE 1

| | | Molar | Co- | |
|---|---|---|---|---|
| | Ab- | extinction | efficient | |
| Unstable | sorption | co- | of | |
| functional | frequency | efficient | compen- | |
| group | (cm−1) | (1/cm/mol) | sation | Model compound |
| —COF | 1883 | 600 | 388 | C₇F₁₅COF |
| —COOH (free) | 1815 | 530 | 439 | H(CF₂)₆COOH |
| —COOH | 1779 | 530 | 439 | H(CF₂)₆COOH |
| (bonded) | | | | |
| —COOCH3 | 1795 | 680 | 342 | C₇F₁₅COOCH₃ |
| —CONH2 | 3436 | 506 | 460 | C₇F₁₅CONH₂ |
| —CH2OH | 3648 | 104 | 2236 | C₇F₁₅CH₂OH |
| —CF2H | 3020 | 8.8 | 26485 | H(CF₂CF₂)₃CH₂OH |
| —OC(═O)O—R | 1817 | — | 1426 | — |

The above fluorination may be performed by bringing fluororesin which has not been fluorinated into contact with a fluorine-containing compound.

Examples of fluorine-containing compounds described above include, but are not limited to, a source of fluorine radicals, which generates a fluorine radical under conditions of fluorination. Examples of sources of fluorine radicals include F₂ gas, CoF₃, AgF₂, UF₆, OF₂, N₂F₂, CF₃OF and fluorinated halogen (e.g., IF₅, ClF₃).

While the concentration of the above source of fluorine radicals such as F₂ gas may be 100%, the source is used after being mixed with inert gas and diluted to preferably 5 to 50% by mass, more preferably 15 to 30% by mass. Examples of inert gas described above include nitrogen gas, helium gas and argon gas, and nitrogen gas is preferred from the economic point of view.

The condition of fluorination is not limited. Molten fluorine resin may be brought into contact with a fluorine-containing compound at usually the melting point of the fluorine resin or lower, preferably a temperature of 20 to 220° C. and more preferably 100 to 200° C. The time of fluorination is usually 1 to 30 hours, and preferably 5 to 25 hours. For the above fluorination, it is preferable that fluorine resin which has not been fluorinated is brought into contact with fluorine gas (F₂ gas).

In the present description, the content of the respective monomer units constituting fluorine resin may be calculated by appropriately combining NMR, FT-IR, elemental analysis and fluorescent X-ray analysis depending on the type of monomers.

It is preferable that the fluororesin has a melt flow rate (MFR) of 0.1 to 50 g/10 minutes at 372° C. and a load of 49 N. The melt flow rate is more preferably 0.5 to 40 g/10 minutes, and further preferably 1 to 30 g/10 minutes. In the present description, MFR is a value obtained by measurement in accordance with ASTM D3307 under the above conditions.

By setting MFR to the above range, the amount of the unstable functional groups can be less than 350, the generation of carbide can be suppressed, and the reduction of conductive foreign matters can be achieved.

When producing a fluororesin film by extrusion melt forming, it is also preferable to adjust the melting temperature, and it is preferable to select a temperature range such that the above-described MFR value can be obtained. Specifically, although the suitable melting temperature varies depending on the resin type, the molecular weight of the resin, or the like, it is preferable to adjust and set the temperature within the range of 340 to 370° C. such that MFR of the resin is within a predetermined range.

The fluororesin film according to the present disclosure may include a component other than fluororesin. Examples of components which the film may include, but are not limited to, a filler such as silica particles and glass staple fiber and thermosetting resin and thermoplastic resin which do not contain fluorine.

The fluororesin-containing composition according to the present disclosure may include spherical silica particles. Spherical silica particles improve flowability of resin, and molding is easy even when a large amount of silica is mixed.

The above spherical silica particles mean those which are substantially a sphere, and have a sphericity of preferably 0.80 or more, more preferably 0.85 or more, further preferably 0.90 or more, and most preferably 0.95 or more. Sphericity is calculated from the area and the circumference of a particle observed in a micrograph taken by SEM based on (sphericity)={4π×(area)÷(circumference) 2}. A sphericity close to 1 means that the particle is close to a sphere. More specifically, an arithmetic average value of 100 particles measured using an image processing device (FPIA-3000 made by Spectris) is used.

The spherical silica particle preferably has a D90/D10 of 2 or more (preferably 2.3 or more, 2.5 or more) and D50 of 10 μm or less when volumes of particles with small particle size are integrated. The spherical silica particle has a D90/D50 of preferably 1.5 or more (more preferably 1.6 or more). The spherical silica particle has a D50/D10 of preferably 1.5 or more (more preferably 1.6 or more). Spherical silica particles with small particle size can enter into the gap between spherical silica particles with large particle size, and this provides excellent filling properties and improves flowability. In particular, it is preferable that in the particle size distribution, frequencies at the side of small particle size are high compared to the Gaussian curve. The particle size may be measured by a laser diffraction scattering particle size distribution meter. Furthermore, it is preferable that coarse particles with a predetermined particle size or more are removed by a filter and the like.

The above spherical silica particle has a water absorption of preferably 1.0% or less, and more preferably 0.5% or less. Water absorption is based on the mass of dried silica particles. For the measurement of water absorption, a dried sample is left at 40° C. and 80% RH for 1 hour and the content of water generated when the sample is heated at 200° C. is measured by a Karl Fischer moisture analyzer, and water absorption is calculated.

For the above spherical silica particles, the fluororesin-containing composition is heated at 600° C. for 30 minutes in air to burn the fluororesin and the spherical silica particles are collected, and then the above parameters may be measured using the above method.

The silica powder according to the present disclosure may be surface-treated. Previous surface treatment can suppress aggregation of silica particles and allows silica particles to be dispersed well in the resin composition.

The above surface treatment is not limited and any known surface treatment may be used. Specific examples include a treatment using a silane coupling agent such as epoxy silane, amino silane, vinyl silane and acrylic silane having a functional group, hydrophobic alkyl silane, phenyl silane and fluorinated alkyl silane, a plasma treatment and a fluorination treatment.

Examples of silane coupling agents described above include epoxy silane such as γ-glycidoxypropyl triethoxysilane and β-(3,4-epoxycyclohexyl)ethyltrimethoxysilane, amino silane such as aminopropyl triethoxysilane and N-phenylaminopropyl trimethoxysilane, vinyl silane such as vinyl trimethoxysilane and acrylic silane such as acryloxy trimethoxysilane.

For the above spherical silica, commercially available silica particles which satisfy the above features may also be used. Examples of commercially available silica particles include Denka Fused Silica FB Grade (made by Denka Company Limited), Denka Fused Silica SFP Grade (made by Denka Company Limited), EXCELICA (made by Tokuyama Corporation), high purity synthesized spherical silica ADMAFINE (made by Admatechs company limited), ADMANANO (made by Admatechs company limited), and ADMAFUSE (made by Admatechs company limited).

The fluororesin film of the present disclosure requires that the number of conductive foreign matters that are present in the film and have a length of 50 μm or more in a flow direction or a width direction of the film is less than 60/square meter.

The number of conductive foreign matters is preferably less than 60/square meter, preferably less than 40/square meter, more preferably less than 20/square meter, and further preferably less than 10/square meter.

The interval between adjacent signal lines of a high-frequency substrate is about 50 μm, and it is believed that the presence of conductive foreign matters across the interval between signal lines causes an increase in the current during voltage application and a decrease in an insulation resistance value. Thus, reducing the number of conductive foreign matters that are present in the film and have a length of 50 μm or more in a flow direction or a width direction of the film can suppress insulation defects of the high-frequency substrate and provide a circuit board with low transmission loss.

In the present disclosure, the conductive foreign matters include metals such as nickel, iron, molybdenum, chromium, aluminum, and copper, which are mixed in the film production process, and carbide caused by the thermal decomposition of unstable functional groups of the fluororesin. As mentioned above, it is believed that nickel includes those derived from a filter used during film production, and other metals are derived from a container, piping, or the like used during production.

In particular, conductive foreign matters are mainly nickel and carbide, thus it is preferable to reduce nickel and carbide. The total number of nickel and carbide that are present in the surface of the film and have a length of 50 μm or more in a flow direction or a width direction of the film is preferably less than 40/square meter, more preferably less than 20/square meter, and further preferably less than 10/square meter.

The conductive foreign matter has an almost constant reflectance in the wavelength band from visible light to near-infrared light. With this property, a conductive foreign matter is defined as one in which the reflectance when irradiated with visible light is close to that when irradiated with near-infrared light.

In the present disclosure, the number of conductive foreign matters is detected by the following method. That is, a film is inspected using a sheet inspection device (product name, etc.: Super NASP-λ, made by OMRON Corporation). The film is passed between a multi-wavelength camera of the sheet inspection device installed in a forming machine and an illumination that irradiates visible light and near-infrared light. At that time, a foreign matter having a metal degree, which is a ratio of reflectance when irradiating the foreign matter with visible light and near-infrared light, of 70 or more is determined as a conductive foreign matter.

The fisheye described in Patent Literatures 2 to 4 above can be visually observed as an opaque white part or a protrusion during film forming. Particularly, in the fluororesin, it is a resin component that exists in the fluororesin as an impurity, such as a component having an abnormally large molecular weight, a component with a large number of TFE components, or a component that is generated by recombination or cross-linking due to heat at the time of forming, thus it does not fall under the above-described conductive foreign matter.

Therefore, even if the number of fisheyes in the film is reduced, the effect of obtaining a circuit board with low transmission loss, which can be effected by reducing conductive foreign matters of a certain size, cannot be expected.

It is preferable that the fluororesin film of the present disclosure has a dielectric loss tangent at 10 GHz of less than 0.0015. The dielectric loss tangent in that range is preferred because loss of electric signals in the circuit can be kept low. The fluororesin film has a dielectric loss tangent of more preferably less than 0.0013, further preferably less than 0.0010, and most preferably 0.00050 or less.

Supposing transmission of signals and transmission and reception with antennas at high frequency, the fluororesin has a dielectric loss tangent at 40 GHz of preferably less than 0.0015, more preferably less than 0.0013, further preferably less than 0.0010, and most preferably 0.00050 or less.

To set the dielectric loss tangent to the above range, it is preferable to use resin in which the number of unstable functional groups is small. It is more preferable to use a fluororesin which has been fluorinated.

It is preferable that the film has an adhesion strength of 0.8 N/mm or more when bonded to metal foil having a surface roughness Rz of 1.5 μm or less.

The above fluororesin film has an adhesion strength of preferably 0.8 N/mm or more, more preferably 0.9 N/mm or more, and further preferably 1.0 N/mm or more when bonded to metal foil having a surface roughness Rz of 1.5 μm or less under conditions of a temperature of the melting point of the fluororesin or more and the melting point +30° C. or less, a pressure of 1.5 to 3.0 MPa and a time of 300 to 600 seconds using a vacuum heat press. The adhesion strength as used herein means adhesion strength of a laminate prepared by bonding under the above conditions, which is measured under the conditions described in Examples.

It is preferable that the one or both surfaces of the above fluororesin film have an adhesion strength of more than 30 N/m when the surfaces of the film are mutually bonded at 200° C. A fluororesin with such adhesion strength has excellent adhesiveness when used in combination with other substrates even after heat treating the fluororesin film. The fluororesin film has an adhesive strength of preferably more than 50 N/m and more preferably more than 100 N/m.

The fluororesin film of the present disclosure has a thickness of preferably 2.5 to 1,000 μm, more preferably 5 to 500 μm, and further preferably 12.5 to 150 μm. The thickness may be selected in consideration of the balance between electric properties and linear expansion coefficient of the laminate and the like.

It is preferable that the fluororesin film of the present disclosure has an area of one square meter or more. In particular, it is preferable that the fluororesin film of the present disclosure is a long film of 100 m or more.

### (Method for Producing Fluororesin Film)

In the following, the method for producing the fluororesin film of the present disclosure explained above will be described in detail. The fluororesin film of the present disclosure is not limited to those produced by the following production method.

For the fluororesin film of the present disclosure, the method of forming film is not limited. Examples thereof include a melt molding method such as extrusion and a casting method in which a solution or a dispersion containing fluororesin is prepared and then applied to and dried on a substrate. Furthermore, the film may be uniaxially or biaxially stretched, or may be an unstretched film.

In the case of the above-described melt forming, the filter in a melt extruder or the like used in the film production is usually a nickel-based, corrosion-resistant filter containing nickel metal or nickel alloy such as Hastelloy, Colmonoy, Monel, or the like. In the present disclosure, the sintered filter is preferred as the filter in terms of filtration accuracy and filter life. By using a sintered filter, it is possible to remove small foreign matters such as relatively small carbide and metal pieces having a length of about 50 μm in a flow direction or a width direction of the film, without openings between meshes.

Examples of such a filter include a filter obtained by stacking multiple nickel or nickel alloy flat woven wire meshes or the like and sintering them to integrate, and a sintered filter material formed by sintering metal long fibers or metal powders.

In the filter, metal adhering to the filter, such as metal powders, wire mesh burrs, or the like caused by metal processing, is present. For example, in a sintered filter, burrs occurred in the wire mesh during sintering the filter may be present. Such metal powders and burrs may be released from the filter and mixed into the fluororesin when the film is produced.

In the present disclosure, it is thus preferable to use a filter that has been dedusted or cleaned. To dedust or clean the filter, immersion cleaning in which a filter is immersed in an immersion tank containing a cleaning liquid or pure water for cleaning, jet cleaning in which a cleaning liquid or pure water is injected toward a metal filter at a high pressure for cleaning, or a cleaning method combining the immersion cleaning and the jet cleaning may be performed. The filter may also be ultrasonically cleaned with a cleaning liquid or pure water. These cleaning steps can reduce nickel and the like that will be released during film production.

In the present disclosure, it is preferable to use an ultrasonically cleaned filter. The method of ultrasonic cleaning is not limited and may be performed by conventional methods. For example, the cleaning time may generally be about 5 minutes to 1 hour.

It is preferable that one or both surfaces of the fluororesin film obtained by such a method are surface-treated and annealed under appropriate conditions.

It is preferable to perform surface treatment and annealing because a fluororesin film in which the oxygen element percentage as measured when heat treatment is performed at 180° C. for 3 minutes and then the state of one or both surfaces of the film is observed by ESCA is 1.35 atom % or more, and an absolute value of the rate of dimensional change in MD and TD before and after heat treatment as measured when the film is heat-treated at 180° C. for 10 minutes and then cooled to 25° C. is 2.0% or less can be obtained.

The effect of surface treatment of fluororesin film to improve adhesiveness tends to be reduced by heating. This is assumed to be because oxygen atoms on the surface are eliminated by heating and thus the amount of oxygen atoms on the surface is reduced. In the step of lamination, sometimes the film is preheated, for example, at a temperature equal to or higher than the glass transition temperature and lower than the melting point of the film, and then laminated to improve productivity. It is preferable that, for the fluorine film which has been exposed to heat in such a way to have sufficient adhesiveness when bonded to metal foil, the film has an oxygen element percentage of 1.35 atom % or more as measured when the film is heat treated at 180° C. for 3 minutes and then the surface to be bonded to metal foil is observed by scanning X-ray photoelectron spectroscopy (XPS/ESCA).

The method of surface modification is not limited, and the surface may be modified by any known method.

For surface modification of fluororesin film, a traditional discharge treatment such as a corona discharge treatment, a glow discharge treatment, a plasma discharge treatment and a sputtering treatment may be used. For example, surface free energy may be controlled by introducing, for example, oxygen gas, nitrogen gas or hydrogen gas into discharge atmosphere. Alternatively, the surface to be modified is exposed to atmosphere of an organic compound-containing inert gas, and high frequency voltage is applied between electrodes to generate discharge and form active species on the surface. Then the functional group of the organic compound is introduced thereinto or a polymerizable organic compound is graft-polymerized to allow the surface modification. Examples of inert gases described above include nitrogen gas, helium gas and argon gas.

Examples of organic compounds in the organic compound-containing inert gas include polymerizable or non-polymerizable oxygen atom-containing organic compounds such as vinyl esters such as vinyl acetate and vinyl formate; acrylates such as glycidyl methacrylate; ethers such as vinyl ethyl ether, vinyl methyl ether and glycidyl methyl ether; carboxylic acids such as acetic acid and formic acid; alcohols such as methyl alcohol, ethyl alcohol, phenol and ethylene glycol; ketones such as acetone and methyl ethyl ketone; carboxylates such as ethyl acetate and ethyl formate; and acrylic acids such as acrylic acid and methacrylic acid. Of them, vinyl esters, acrylates and ketones are preferred, and in particular vinyl acetate and glycidyl methacrylate are preferred because the modified surface is less likely to be deactivated, i.e., has long life and can be easily handled.

The concentration of the organic compound in the above organic compound-containing inert gas varies depending on its type and the type of fluororesins of which surface is to be modified. The concentration is usually 0.1 to 3.0% by volume, preferably 0.1 to 1.0% by volume, more preferably 0.15 to 1.0% by volume, and further preferably 0.30 to 1.0% by volume. Conditions of discharge may be appropriately selected depending on the intended degree of surface modification, the type of fluororesins and the type and the concentration of organic compounds. Usually the discharge treatment is performed in the amount of discharge of 50 to 1500 W·minute/m², and preferably 70 W·minute/m² or more and 1400 W·minute/m² or less. The discharge treatment may be performed at any temperature of 0° C. or more to 100° C. or less. The temperature is preferably 80° C. or less in consideration of elongation and wrinkles of film. For the degree of surface modification, an abundance of oxygen element in observation by ESCA is 2.6% or more, preferably 2.8% or more, more preferably 3.0% or more, and further preferably 3.5% or more in consideration of reduction of adhesiveness on the surface due to heat in post-processing. The upper limit is not limited, but is preferably 25.0% or less in consideration of productivity and impacts on other physical properties. The abundance of nitrogen element is not limited, but is preferably 0.1% or more. The fluororesin film has a thickness of preferably 2.5 to 1,000 μm, more preferably 5 to 500 μm and further preferably 7 to 150 μm per film.

It is preferable that in the production of the fluororesin film of the present disclosure, annealing treatment is performed after the above surface treatment. Furthermore, heat treatment may be performed in the process of lamination of the film and other materials such as metal foil. These heat treatments cause a reduction in the amount of oxygen on the surface of the fluororesin film. Thus, it is preferable to modify the surface under conditions that provide a sufficient amount of oxygen on the surface when the fluororesin film and other materials such as metal foil are actually stacked.

### (Annealing Treatment)

Annealing treatment may be performed by heat treatment. In this heat treatment, for example, film may be passed through a heating furnace by a roll-to-roll method.

The temperature of annealing treatment is preferably the glass transition temperature −20° C. or more and less than the melting point, more preferably the glass transition temperature or more and the melting point −20° C. or less, and further preferably the glass transition temperature or more and the melting point −60° C. or less. The time of annealing treatment is not limited, and may be appropriately adjusted to, for example, 0.5 to 60 minutes. When the film which has been passed through the annealing furnace and remains at high temperature comes into contact with the roll of the winding apparatus, the film is likely to be deformed (waved) due to heat shrinkage caused by the temperature change. To avoid this, the film may be cooled by passing it through a cooling zone after the high temperature annealing zone and then taken up on the winding apparatus. The method of cooling is not limited, and the film may be cooled by cool air or a cooling roll. It is preferable that the temperature of the film is brought to less than the glass transition temperature.

When the film is heated by the above roll-to-roll method, the tension may be appropriately set depending on the thickness of the film and the set temperature, and is preferably 20 N/m or less. Heating under these conditions is preferable because internal stress can be sufficiently released and dimensional change and the like does not occur.

The order of the above surface treatment and annealing treatment is not limited. The number of times of the respective steps to be executed is not limited to once, either, and may be executed twice or more. Since tension is applied to the film in the step of surface treatment, it is preferable to perform the surface treatment first and then perform the annealing treatment so as to control the thermal shrinkage rate. Furthermore, a slit with a predetermined width and length may be formed before or after these treatments. It is preferable that in those cases the tension is adjusted so that the film is not elongated.

The fluororesin film of the present disclosure may be stacked to other substrates and used as a sheet for a printed wiring board.

The other substrates described above include a metal foil, a resin film other than the fluororesin film, and the like.

The present disclosure also comprises a metal-clad laminate comprising metal foil and any of the fluororesin films described above as essential layers.

It is preferable that the metal-clad laminate further comprises another layer in addition to the metal foil and the fluororesin film. It is preferable that the other layer in addition to the metal foil and the fluororesin film is at least one selected from the group consisting of polyimide, liquid crystal polymer, polyphenylene sulfide, a cycloolefin polymer, polystyrene, epoxy resin, bismaleimide, polyphenylene oxide, polyphenylene ether and polybutadiene.

It is preferable that the metal foil has a surface roughness Rz of 1.5 μm or less.

It is preferable that the metal-clad laminated board has an adhesion strength between the metal foil and the fluororesin film of 0.8 N/mm or more.

The present disclosure also includes a substrate for circuit comprising any of the metal-clad laminate described above.

The present disclosure also includes a metal-clad laminate in which metal foil is bonded to one or both surfaces of the above fluororesin film. As described above, the film comprising the fluororesin of the present disclosure has an improved bonding processing yield to a substrate and excellent adhesiveness.

It is preferable that the above metal foil has Rz of 1.5 μm or less. In other words, the fluororesin film according to the present disclosure has excellent adhesion even to highly smooth metal foil having Rz of 1.5 μm or less. The metal foil may have Rz of 1.5 μm or less on at least the surface to be bonded to the above fluororesin film, and the value of Rz on the other surface is not limited.

The Rz of the metal foil is a value obtained by measuring the maximum height Rz in the range of 200 μm² using a color 3D laser microscope VK-9700 made by KEYENCE CORPORATION.

The thickness of the metal foil is not limited, and the metal foil has a thickness of preferably 1 to 100 μm, more preferably 5 to 50 μm, and further preferably 9 to 35 μm.

It is preferable that the metal foil is copper foil.

The above copper foil is not limited and specific examples thereof include rolled copper foil and electrolytic copper foil.

Copper foil having Rz of 1.5 μm or less is not limited and commercially available copper foil may be used. Examples of commercially available copper foil having Rz of 1.5 μm or less include electrolytic copper foil CF-T9DA-SV-18 (thickness 18 μm, Rz 0.85 μm) (made by Fukuda Metal Foil & Powder Co., Ltd.).

The above metal foil may be surface-treated to improve adhesion strength to the fluororesin film of the present disclosure.

The surface treatment includes, but is not limited to, a silane coupling treatment, a plasma treatment, a corona treatment, a UV treatment and an electron beam treatment. The reactive functional group of the silane coupling agent is not limited, and the silane coupling agent may preferably include at least one group selected from an amino group, a (meth)acrylic group, a mercapto group and an epoxy group at the terminal in view of adhesion to the resin substrate. Examples of hydrolytic groups include, but are not limited to, an alkoxy group such as a methoxy group and an ethoxy group. An anti-rust layer (an oxide coating such as chromate) and a heat resistant layer may be formed on the metal foil used in the present disclosure.

Surface-treated metal foil having a surface-treated layer of the above silane compound on the surface may be produced by preparing a solution containing a silane compound and surface treating the metal foil using the solution.

The metal foil may have a roughened layer on the surface in order to increase adhesion to the resin substrate and the like.

If roughening treatment is likely to degrade properties required in the present disclosure, the amount of roughening particles to be electrodeposited on the metal foil surface may be reduced if necessary, or roughening treatment may not be performed.

One or more layers selected from the group consisting of a heat-resisting treated layer, an anti-rust layer and a chromate-treated layer may be formed between the metal foil and the surface-treated layer in order to improve various properties. Those layers may be a single layer or multiple layers.

It is preferable that the above laminate has an adhesion strength between the metal foil and the fluororesin film of 0.8 N/mm or more. Using the method described above allows the laminate to have such adhesion strength. By setting the adhesion strength to 0.9 N/mm or more, or 1.0 N/mm or more, the laminate may be suitably used as a metal-clad laminated board or a substrate for circuits. The adhesion strength as used herein means the adhesion strength measured under conditions described in Examples. In the case of a laminate prepared by bonding metal foil to the surface-treated side of a fluororesin film having only one side surface-treated, the non-treated side of the fluororesin film may also be surface-modified in order to improve adhesiveness of the laminate to other materials.

The present disclosure also includes a laminate comprising a metal foil layer, the above fluororesin film and a substrate layer. The substrate layer is not limited. It is preferable that the laminate has a fabric layer made of glass fiber and a resin film layer.

The above fabric layer made of glass fiber is made of, for example, glass cloth or glass non-woven fabric.

Commercially available glass cloth may be used, and glass cloth which has been treated with a silane coupling agent is preferred in order to improve affinity with fluororesin. Materials of glass cloth include E-glass, C-glass, A-glass, S-glass, D-glass, NE-glass and low dielectric glass. E-glass, S-glass and NE-glass are preferred because they are readily available. The type of weaving fiber may be plain weave or twill weave. The glass cloth has a thickness of usually 5 to 90 μm and preferably 10 to 75 μm. It is preferable to use the glass cloth thinner than the fluororesin film used.

For the above laminate, glass non-woven fabric may be used as the fabric layer made of glass fiber. Glass non-woven fabric refers to a fabric prepared by bonding glass staple fiber with a small amount of a binder compound (resin or an inorganic substance), or fabric in which pieces of glass staple fiber are entangled to maintain the shape without using a binder compound. Commercially available ones may be used. The glass staple fiber has a diameter of preferably 0.5 to 30 μm, and a fiber length of preferably 5 to 30 mm. Examples of binder compounds include a resin such as epoxy resin, acrylic resin, cellulose, polyvinyl alcohol and fluororesin, and an inorganic compound such as a silica compound. The amount of the binder compound used is usually 3 to 15% by mass based on the glass staple fiber. Materials of glass staple fiber include E-glass, C-glass, A-glass, S-glass, D-glass, NE-glass and low dielectric glass. The glass non-woven fabric has a thickness of usually 50 μm to 1,000 μm, and preferably 100 to 900 μm. The thickness of the glass non-woven fabric in the present disclosure refers to values measured according to JIS P8118:1998 using Digital Gauge DG-925 (load 110 g, diameter 10 mm) made by Ono Sokki Co., Ltd. To improve affinity with fluororesin, the glass non-woven fabric may be treated with a silane coupling agent.

Since most glass non-woven fabrics have a very high porosity of 80% or more, it is preferable to use a glass non-woven fabric thicker than the sheet of fluororesin; and it is preferable to compress glass non-woven fabric under pressure and then used.

The above fabric layer made of the glass fiber may be a layer in which glass cloth and glass non-woven fabric are stacked. This combines both features and provides suitable qualities.

The fabric layer made of the glass fiber may be in the form of prepreg which has been impregnated with resin.

In the above laminate, the fabric layer made of glass fiber may be bonded to the fluororesin film at the interface, or the fabric layer made of glass fiber may be partly or entirely impregnated with the fluororesin film.

Furthermore, prepreg may be prepared by impregnating fabric made of glass fiber with a fluororesin composition. The prepreg prepared as described above may be stacked with the fluororesin film of the present disclosure. In that case, the fluororesin composition used for preparing prepreg is not limited, and the fluororesin film of the present disclosure may be used.

Heat resistant resin film and thermosetting resin film are preferred as the resin film used as the above substrate layer. Examples of heat resistant resin film include polyimide, liquid crystal polymer, polyphenylene sulfide, cycloolefin polymer and polystyrene. Examples of thermosetting resins include those including epoxy resin, bismaleimide, polyphenylene oxide, polyphenylene ether and polybutadiene.

The heat resistant resin film and the thermosetting resin film may also include reinforcing fiber. Examples of reinforcing fibers include, but are not limited to, glass cloth, in particular preferably low dielectric glass cloth.

Properties of the heat resistant resin film and the thermosetting resin film, such as dielectric properties, linear expansion coefficient and water absorption ratio are not limited. For example, the dielectric constant at 20 GHz is preferably 3.8 or less, more preferably 3.4 or less and further preferably 3.0 or less. The dielectric loss tangent at 20 GHz is preferably 0.0030 or less, more preferably 0.0025 or less, and further preferably 0.0020 or less. The linear expansion coefficient is preferably 100 ppm/° C. or less, more preferably 70 ppm/° C. or less, further preferably 40 ppm/° C. or less, and most preferably 20 ppm/° C. or less. The water absorption is preferably 1.0% or less, more preferably 0.5% or less, and further preferably 0.1% or less.

The fluororesin film of the present disclosure may be used for a laminate comprising metal foil, a substrate layer and the fluororesin film described above.

The method for stacking the metal foil, a substrate layer and the fluororesin film is not limited, and includes the following two.

(i) A method in which metal foil, a substrate layer and a fluororesin film which has been previously molded are stacked by applying pressure using a roll-to-roll process or a pressing machine while heating.

(ii) A method in which fluororesin film is bonded to one side of metal foil to produce a laminate and the laminate is stacked on a substrate layer by applying pressure while heating.

In the above method (i), when stacking the metal foil, the substrate layer and the fluororesin film, at least one surface of at least one layer of the metal foil, the substrate layer and the fluororesin film may be surface-treated and then bonded to other layers to improve adhesion of each layer.

Furthermore, the surface-treated surface of the metal foil, the substrate layer, or the fluororesin film may be further treated with a coupling agent or the like to improve adhesion. Alternatively, an adhesive layer may be provided between the layers with or without prior surface treatment.

An anti-rust layer (for example, an oxide coating such as chromate) or a heat-resistant layer may be formed on the surface of the metal foil.

In the above method (ii), when producing a laminate in which the fluororesin film is bonded to one side of the metal foil, at least one surface of at least one layer of the metal foil and the fluororesin film may be surface-treated and then bonded to improve adhesion of each layer.

Furthermore, the surface-treated surface of the metal foil or the fluororesin film may be further treated with a coupling agent or the like to improve adhesion.

Alternatively, an adhesive layer may be provided between the layers with or without prior surface treatment.

In addition, before or after stacking the laminate in which the fluororesin film is bonded to one side of the metal foil, a surface treatment may be performed on the surface of the fluororesin film on which the substrate layer is stacked to improve adhesion between the fluororesin film and the substrate layer.

Alternatively, a surface treatment may be performed on the substrate layer to obtain a similar effect.

Furthermore, the surface-treated surface of the fluororesin film or the substrate layer may be further treated with a coupling agent or the like to improve adhesion.

Alternatively, an adhesive layer may be provided between the layers with or without prior surface treatment.

An anti-rust layer (for example, an oxide coating such as chromate) or a heat-resistant layer may be formed on the surface of the metal foil.

In these methods, when a metal-clad laminate which essentially comprises the fluororesin film and metal foil is stacked on a substrate layer such as a fabric layer made of glass fiber or resin film layer, the side of the fluororesin film layer of the metal-clad laminate may be stacked by bonding to the substrate layer. In that case, the side of the fluororesin film layer of the metal-clad laminate may be surface-treated before lamination to improve adhesion properties. The surface treatment at that stage is not limited, and examples thereof include plasma treatment described above.

For the above laminate, the order of lamination of the metal foil layer, the substrate layer and the fluororesin film described above, and the method for producing them are not limited. The layer structure may be determined depending on the purposes of use.

Specifically, the order of lamination may be substrate layer/fluororesin film/metal foil layer, metal foil layer/fluororesin film/substrate layer/fluororesin film/metal foil layer, and metal foil layer/substrate layer/fluororesin film/substrate layer/metal foil layer.

Furthermore, the laminate may have other layers where necessary.

The metal foil for the above laminate may be the same as the metal foil for the laminate with the fluororesin film described in detail above.

To obtain the above structure of the laminate, the fluororesin film of the present disclosure is used with metal foil bonded to one or both sides. As described above, the fluororesin film of the present disclosure has excellent adhesiveness. Thus the fluororesin film has excellent adhesiveness even to highly smooth metal foil having Rz of 1.5 μm or less. It is preferable that the laminate has an adhesion strength between the metal foil and the fluororesin film of preferably 0.8 N/mm or more. By setting the adhesion strength to 0.9 N/mm or more, more preferably 1.0 N/mm or more, the laminate can be suitably used as a metal-clad laminated board and a substrate for circuits. The adhesion strength as used herein means the adhesion strength measured under conditions described in Examples.

Certain irregularities have been formed on the surface of metal foil to be used for a substrate for circuits in order to provide adhesion to an insulation layer. However, irregularities are not preferred because those irregularities on the surface of metal foil cause loss of electric signals in high frequency applications. The above laminate has suitable adhesiveness even to highly smooth metal foil and thus can be suitably used as a substrate for circuits.

The fluororesin film of the present disclosure has the advantage that no defects occur in lamination and the film is highly adhesive to metal foil. Since the fluororesin film is adhesive even to highly smooth metal foil having Rz of 1.5 μm or less, a laminate which can be suitably used as a metal-clad laminate and a substrate for circuits, and for flat cable and coverlay can be obtained.

It is preferable that the film is used for a metal-clad laminated board.

In the present disclosure, high frequency circuits include not only circuits transmitting only high frequency signals but also circuits including, on the same plane, channels which transmit non-high frequency signals, such as a channel which converts high frequency signals into low frequency signals and output the resulting low frequency signals to the outside and a channel for supplying a power source for driving a component corresponding to high frequency. Furthermore, the laminate may also be used as a circuit board for antennas and filters.

### EXAMPLES

The present disclosure will be described in more detail with reference to Examples. The present disclosure is not limited to the following Examples. In the following Examples, the ratio is expressed as a molar ratio.

### [Fluororesin]

PFA1: TFE/PPVE copolymer, composition (molar ratio): TFE/PPVE=98.6/1.4, MFR 15.2 g/10 min, melting point 309.5° C., glass transition temperature 93° C., the number of unstable functional groups after film forming and surface treatment: 324 per 1×10⁶ carbon atoms in the main chain of fluororesin

### [Fluororesin]

PFA2: TFE/PPVE copolymer, composition (molar ratio): TFE/PPVE=97.7/2.3, MFR 14.6 g/10 min, melting point 300.9° C., glass transition temperature 93° C., the number of unstable functional groups after film forming and surface treatment: 192 per 1×10⁶ carbon atoms in the main chain of fluororesin

### [Fluororesin]

PFA3: Fluorinated TFE/PPVE copolymer, composition (molar ratio): TFE/PPVE=97.7/2.3, MFR 15.0 g/10 min, melting point 300.9° C., glass transition temperature 93° C., the number of unstable functional groups after film forming and surface treatment: 8 per 1×10⁶ carbon atoms in the main chain of fluororesin

### [Fluororesin]

PFA4: TFE/PPVE copolymer, composition (molar ratio): TFE/PPVE=97.2/2.8, MFR 64 g/10 min, melting point 284° C., glass transition temperature 90° C., the number of unstable functional groups after film forming and surface treatment: 507 per 1×10⁶ carbon atoms in the main chain of fluororesin

(Composition of Polymer) The composition of polymer was measured by 19F-NMR.

### (Melting Point)

The melting point was calculated from the melting peak measured using a DSC apparatus while increasing the temperature at a temperature increase rate of 10° C./minute.

### (Glass Transition Temperature)

The glass transition temperature was calculated from the tan δ peak measured using a solid dynamic mechanical analyzer (DMA) at a frequency of 10 Hz and a strain of 0.1% while increasing the temperature at a temperature increase rate of 5° C./minute.

### (Melt Flow Rate: MFR)

The melt flow rate was measured in accordance with ASTM D3307 under conditions of a temperature of 372° C. and a load of 5.0 kg.

### (Thickness of Fluororesin Film)

The thickness of the fluororesin film was measured by a micrometer.

### (Number of Unstable Functional Groups)

For the number of unstable functional groups, the film was analyzed by using FT-IR Spectrometer 1760X (made by Perkin-Elmer).

### (ESCA Analysis of Surface of Fluororesin Film)

The surface of the fluororesin film was observed using scanning X-ray photoelectron spectroscopy (XPS/ESCA) PHI 5000 Versa Probe II (made by ULVAC-PHI).

### (Surface Roughness of Copper Foil)

The catalog value of electrolytic copper foil CF-T9DA-SV-18 (thickness 18 μm/Rz 0.85 μm) (made by Fukuda Metal Foil & Powder Co., Ltd.) was used.

### (Adhesion Strength Between Copper Foil and Fluororesin Film)

A fluororesin film which had not been preheated or which had been preheated at the glass transition temperature or more and less than the melting point was stacked on copper foil in the order of copper foil/fluororesin film/copper foil to prepare a laminate by using a vacuum heat press. An aluminum plate was attached to one side of the laminate with adhesive tape, and peel strength was measured by sandwiching and pulling copper foil at a width of 10 mm in the direction at 90° relative to the plane of the laminate at a rate of 50 mm per minute using Tensilon Universal Testing Machine (made by Shimadzu Corporation). The resulting value was defined as adhesion strength.

### (Measurement of the Number of Conductive Foreign Matters)

### Measurement of the Number of Conductive Foreign Matters

The number of conductive foreign matters was detected by the following method. That is, the film was inspected using a sheet inspection device (product name, etc.: Super NASP-λ, made by OMRON Corporation). The film was passed between a multi-wavelength camera of the inspection device installed in a forming machine and an illumination that irradiates visible light and near-infrared light. At that time, a foreign matter having a metal degree, which is a ratio of reflectance when irradiating the foreign matter with visible light and infrared light, of 70 or more is determined as a conductive foreign matter.
Nickel: those with a metal degree of 88 to 92
Carbide: those with a metal degree of 95 to 100
Other conductive foreign matters: those with metal degree of 70 or more and outside the above ranges

The number of conductive foreign matter having a length of 50 μm or more in the flow direction or the width direction of the film was detected.

### (Appearance Observation)

The foreign matters in a film of 1 m² were visually observed, and the number of black foreign matters was counted using a loupe. As result of the observation, the film having a count of less than 10 per 1 m² was evaluated as ⊙, the film having a count of 10 or more and less than 60 per 1 m² was evaluated as ◯, and the film having a count of 60 or more per 1 m² was evaluated as x. The black foreign matters that could be visually observed were regarded as all conductive foreign matters including nickel and carbide.

### (Evaluation of Yield of Bonding)

A fluororesin film which had not been preheated or which had been preheated at a temperature equal to or higher than the glass transition temperature and lower than the melting point was cut into a size of 25 cm×40 cm, stacked in the order of copper foil/fluororesin film, and subjected to a vacuum heat press to prepare a laminate. The film bonded to the copper foil of the laminate was visually inspected, and the identified foreign matters were observed from the film surface side with a differential interference microscope (product name: LV100ND, made by Nikon Corporation). For conductive foreign matters, those looked black in the vicinity thereof were regarded as carbide, and those in which metallic gloss was observed were regarded as metal foreign matters. Those in which only unevenness was observed were regarded as fisheyes that are non-conductive foreign matters.

For protrusions derived from conductive foreign matters in an area of 25 cm×40 cm, the case having 1 or less protrusions was evaluated as ⊙, the case having 2 or more and 6 or less protrusions was evaluated as ◯, and the case having 7 or more protrusions was evaluated as x.

### Example 1

### [Method for Producing Film]

PFA1 pellets were fed into a 360° C. extruder in which an ultrasonically cleaned, nickel filter of stacked multiple meshes of #300 or more was inserted between a screw and a die, extruded from a 1, 700 mm wide T die, picked up onto a metal cooling roll, and further taken up on a winding core to form a roll film of 1, 300 mm width and 50 μm thickness.

The conductive foreign matters were inspected at the time of this film forming.

### [Surface Treatment of Film]

Then, both surfaces of the resulting long roll film were surface-treated (both surfaces of the film were subjected to corona discharge treatment by passing the film continuously along a roll-shaped ground electrode with allowing nitrogen gas containing 0.50% by volume of vinyl acetate to flow near the discharge electrode and the roll-shaped ground electrode in a corona discharge device at an amount of discharge of 1, 324 W·minute/m²). The surface-treated long film was taken up in the form of a roll.

The appearance of the resulting film was observed.

### [Bonding to Copper Foil]

The fluororesin film was stacked on electrolytic copper foil CF-T9DA-SV-18 (thickness 18 μm/Rz 0.85 μm) (made by Fukuda Metal Foil & Powder Co., Ltd.) so that the surface which had been surface-treated was in contact with the copper foil, and the two were bonded by heat pressing using a vacuum heat press (Model: MKP-1000HVWH-S7 made by Mikado Technos Co., Ltd.) at a press temperature of 320° C. for a preheating time of 60 seconds at a pressure of 1.5 MPa for a pressing time of 300 seconds to give a bonded product having a size of 25 cm×40 cm.

Yield was evaluated for a bonded product having a layer structure of copper foil/fluororesin film. Similarly, adhesion strength was measured for a bonded product having a layer structure of copper foil/fluororesin film/copper foil.

### Example 2

A film with a film thickness of 25 μm was formed in the same manner as in Example 1. The conductive foreign matters at the time of film forming were inspected, the appearance of the film was observed, the yield after bonding was evaluated, and the adhesion strength was measured.

### Example 3

A film with a film thickness of 12.5 μm was formed in the same manner as in Example 1. The conductive foreign matters at the time of film forming were inspected, the appearance of the film was observed, the yield after bonding was evaluated, and the adhesion strength was measured.

### Example 4

A film with a film thickness of 50 μm was formed in the same manner as in Example 1 except for using PFA2. The conductive foreign matters at the time of film forming were inspected, the appearance of the film was observed, the yield after bonding was evaluated, and the adhesion strength was measured.

### Example 5

A film with a film thickness of 25 μm was formed in the same manner as in Example 4. The conductive foreign matters at the time of film forming were inspected, the appearance of the film was observed, the yield after bonding was evaluated, and the adhesion strength was measured.

### Example 6

A film with a film thickness of 12.5 μm was formed in the same manner as in Example 4. The conductive foreign matters at the time of film forming were inspected, the appearance of the film was observed, the yield after bonding was evaluated, and the adhesion strength was measured.

### Example 7

A film with a film thickness of 50 μm was formed in the same manner as in Example 1 except for using PFA3. The conductive foreign matters at the time of film forming were inspected, the appearance of the film was observed, the yield after bonding was evaluated, and the adhesion strength was measured.

### Example 8

A film with a film thickness of 25 μm was formed in the same manner as in Example 7. The conductive foreign matters at the time of film forming were inspected, the appearance of the film was observed, the yield after bonding was evaluated, and the adhesion strength was measured.

### Example 9

A film with a film thickness of 12.5 μm was formed in the same manner as in Example 7. The conductive foreign matters at the time of film forming were inspected, the appearance of the film was observed, the yield after bonding was evaluated, and the adhesion strength was measured.

### Example 10

PFA1 pellets were fed into a 360° C. extruder in which a sintered, ultrasonically cleaned, nickel filter of stacked multiple meshes of #300 or more was inserted between a screw and a die, extruded from a 1, 700 mm wide T die, picked up onto a metal cooling roll, and further taken up on a winding core to form a roll film of 1, 300 mm width and 50 μm thickness.

In the same manner as in Example 1, the conductive foreign matters at the time of film forming were inspected, the appearance of the film was observed, the yield after bonding was evaluated, and the adhesion strength was measured.

### Example 11

A film with a film thickness of 25 μm was formed in the same manner as in Example 10. The conductive foreign matters at the time of film forming were inspected, the appearance of the film was observed, the yield after bonding was evaluated, and the adhesion strength was measured.

### Example 12

A film with a film thickness of 12.5 μm was formed in the same manner as in Example 10. The conductive foreign matters at the time of film forming were inspected, the appearance of the film was observed, the yield after bonding was evaluated, and the adhesion strength was measured.

### Example 13

A film with a film thickness of 50 μm was formed in the same manner as in Example 10 except for using PFA2. The conductive foreign matters at the time of film forming were inspected, the appearance of the film was observed, the yield after bonding was evaluated, and the adhesion strength was measured.

### Example 14

A film with a film thickness of 25 μm was formed in the same manner as in Example 13. The conductive foreign matters at the time of film forming were inspected, the appearance of the film was observed, the yield after bonding was evaluated, and the adhesion strength was measured.

### Example 15

A film with a film thickness of 12.5 μm was formed in the same manner as in Example 13. The conductive foreign matters at the time of film forming were inspected, the appearance of the film was observed, the yield after bonding was evaluated, and the adhesion strength was measured.

### Example 16

A film with a film thickness of 50 μm was formed in the same manner as in Example 10 except for using PFA3. The conductive foreign matters at the time of film forming were inspected, the appearance of the film was observed, the yield after bonding was evaluated, and the adhesion strength was measured.

### Example 17

A film with a film thickness of 25 μm was formed in the same manner as in Example 16. The conductive foreign matters at the time of film forming were inspected, the appearance of the film was observed, the yield after bonding was evaluated, and the adhesion strength was measured.

### Example 18

A film with a film thickness of 12.5 μm was formed in the same manner as in Example 16. The conductive foreign matters at the time of film forming were inspected, the appearance of the film was observed, the yield after bonding was evaluated, and the adhesion strength was measured.

### Comparative Example 1

PFA4 pellets were fed into a 360° C. extruder in which an uncleaned, unsintered, nickel filter of stacked multiple meshes of #300 or more was inserted between a screw and a die, extruded from a 1,700 mm wide T die, picked up onto a metal cooling roll, and further taken up on a winding core to form a roll film of 1, 300 mm width and 50 μm thickness.

In the same manner as in Example 1, the conductive foreign matters at the time of film forming were inspected, the appearance of the film was observed, the yield after bonding was evaluated, and the adhesion strength was measured.

### Comparative Example 2

A film with a film thickness of 25 μm was formed in the same manner as in Comparative Example 1. The conductive foreign matters at the time of film forming were inspected, the appearance of the film was observed, the yield after bonding was evaluated, and the adhesion strength was measured.

### Comparative Example 3

A film with a film thickness of 12.5 μm was formed in the same manner as in Comparative Example 1. The conductive foreign matters at the time of film forming were inspected, the appearance of the film was observed, the yield after bonding was evaluated, and the adhesion strength was measured.

### Comparative Example 4

PFA1 pellets were fed into a 360° C. extruder in which a sintered nickel filter of stacked multiple meshes of #300 or more was inserted between a screw and a die, extruded from a 1,700 mm wide T die, picked up onto a metal cooling roll, and further taken up on a winding core to form a roll film of 1, 300 mm width and 50 μm thickness.

In the same manner as in Example 1, the conductive foreign matters at the time of film forming were inspected, the appearance of the film was observed, the yield after bonding was evaluated, and the adhesion strength was measured.

### Comparative Example 5

A film with a film thickness of 25 μm was formed in the same manner as in Comparative Example 4. The conductive foreign matters at the time of film forming were inspected, the appearance of the film was observed, the yield after bonding was evaluated, and the adhesion strength was measured.

### Comparative Example 6

A film with a film thickness of 12.5 μm was formed in the same manner as in Comparative Example 4. The conductive foreign matters at the time of film forming were inspected, the appearance of the film was observed, the yield after bonding was evaluated, and the adhesion strength was measured.

The results of Examples 1 to 18 are shown in Table 2.

TABLE 2

| | | Exam- | Exam- | Exam- | Exam- | Exam- | Exam- | Exam- | Exam- | Exam- | Exam- | Exam- | Exam- | Exam- |
|---|---|---|---|---|---|---|---|---|---|---|---|---|---|---|
| | | ple | ple | ple | ple | ple | ple | ple | ple | ple | ple | ple | ple | ple |
| | | 1 | 2 | 3 | 4 | 5 | 6 | 7 | 8 | 9 | 10 | 11 | 12 | 13 |
| Film | Unstable | 324 | 324 | 324 | 192 | 192 | 192 | 8 | 8 | 8 | 324 | 324 | 324 | 192 |
| | functional | | | | | | | | | | | | | |
| | group | | | | | | | | | | | | | |
| | Number per | | | | | | | | | | | | | |
| | 1 × 10⁶ per | | | | | | | | | | | | | |
| | carbon | | | | | | | | | | | | | |
| | atoms | | | | | | | | | | | | | |
| | in main | | | | | | | | | | | | | |
| | chain of | | | | | | | | | | | | | |
| | fluororesin | | | | | | | | | | | | | |
| | Presence or | pre- | pre- | pre- | pre- | pre- | pre- | pre- | pre- | pre- | pre- | pre- | pre- | pre- |
| | absence of | sence | sence | sence | sence | sence | sence | sence | sence | sence | sence | sence | sence | sence |
| | ultrasonic | | | | | | | | | | | | | |
| | cleaning | | | | | | | | | | | | | |
| | of filter | | | | | | | | | | | | | |
| | Presence or | ab- | ab- | ab- | ab- | ab- | ab- | ab- | ab- | ab- | pre- | pre- | pre- | pre- |
| | absence of | sence | sence | sence | sence | sence | sence | sence | sence | sence | sence | sence | sence | sence |
| | sintering | | | | | | | | | | | | | |
| | treatment of | | | | | | | | | | | | | |
| | filter | | | | | | | | | | | | | |
| | Average | 50 | 25 | 12.5 | 50 | 25 | 12.5 | 50 | 25 | 12.5 | 50 | 25 | 12.5 | 50 |
| | film | | | | | | | | | | | | | |
| | thickness | | | | | | | | | | | | | |
| | of | | | | | | | | | | | | | |
| | surface (um) | | | | | | | | | | | | | |
| | Number of | 33 | 32 | 28 | 28 | 24 | 25 | 1 | 0 | 0 | 7 | 6 | 4 | 3 |
| | carbide | | | | | | | | | | | | | |
| | having | | | | | | | | | | | | | |
| | length of | | | | | | | | | | | | | |
| | 50 μm | | | | | | | | | | | | | |
| | or more | | | | | | | | | | | | | |
| | (number/ | | | | | | | | | | | | | |
| | m²) | | | | | | | | | | | | | |
| | Number of | 5 | 5 | 4 | 4 | 5 | 4 | 5 | 4 | 3 | 2 | 2 | 1 | 1 |
| | nickel | | | | | | | | | | | | | |
| | having | | | | | | | | | | | | | |
| | length of | | | | | | | | | | | | | |
| | 50 μm | | | | | | | | | | | | | |
| | or more | | | | | | | | | | | | | |
| | (number/ | | | | | | | | | | | | | |
| | m²) | | | | | | | | | | | | | |
| | Number of | 40 | 39 | 35 | 34 | 34 | 30 | 6 | 5 | 4 | 10 | 9 | 8 | 5 |
| | conductive | | | | | | | | | | | | | |
| | foreign | | | | | | | | | | | | | |
| | matters | | | | | | | | | | | | | |
| | having size | | | | | | | | | | | | | |
| | of 50 μm or | | | | | | | | | | | | | |
| | more | | | | | | | | | | | | | |
| | in surface | | | | | | | | | | | | | |
| | (number/ | | | | | | | | | | | | | |
| | m²) | | | | | | | | | | | | | |
| | Appearance | ◯ | ◯ | ◯ | ◯ | ◯ | ◯ | ⊙ | ⊙ | ⊙ | ⊙ | ⊙ | ⊙ | ⊙ |
| Stacking | Yield of | ◯ | ◯ | ◯ | ◯ | ◯ | ◯ | ⊙ | ⊙ | ⊙ | ⊙ | ⊙ | ⊙ | ⊙ |
| of copper | bonding | | | | | | | | | | | | | |
| foil and | Adhesion | 1 | 1.1 | 1 | 1.2 | 1.1 | 1 | 1.1 | 1.1 | 1.1 | 1.2 | 1.2 | 1.1 | 1.2 |
| film | strength to | | | | | | | | | | | | | |
| | copper foil | | | | | | | | | | | | | |
| | (N/mm) | | | | | | | | | | | | | |

| | | Exam- | Exam- | Exam- | Exam- | Exam- |
|---|---|---|---|---|---|---|
| | | ple | ple | ple | ple | ple |
| | | 14 | 15 | 16 | 17 | 18 |
| Film | Unstable | 192 | 192 | 8 | 8 | 8 |
| | functional | | | | | |
| | group | | | | | |
| | Number per | | | | | |
| | 1 × 10⁶ per | | | | | |
| | carbon | | | | | |
| | atoms | | | | | |
| | in main | | | | | |
| | chain of | | | | | |
| | fluororesin | | | | | |
| | Presence or | pre- | pre- | pre- | pre- | pre- |
| | absence of | sence | sence | sence | sence | sence |
| | ultrasonic | | | | | |
| | cleaning | | | | | |
| | of filter | | | | | |
| | Presence or | pre- | pre- | pre- | pre- | pre- |
| | absence of | sence | sence | sence | sence | sence |
| | sintering | | | | | |
| | treatment of | | | | | |
| | filter | | | | | |
| | Average | 25 | 12.5 | 50 | 25 | 12.5 |
| | film | | | | | |
| | thickness | | | | | |
| | of | | | | | |
| | surface (um) | | | | | |
| | Number of | 2 | 1 | 0 | 0 | 0 |
| | carbide | | | | | |
| | having | | | | | |
| | length of | | | | | |
| | 50 μm | | | | | |
| | or more | | | | | |
| | (number/ | | | | | |
| | m²) | | | | | |
| | Number of | 2 | 1 | 1 | 0 | 0 |
| | nickel | | | | | |
| | having | | | | | |
| | length of | | | | | |
| | 50 μm | | | | | |
| | or more | | | | | |
| | (number/ | | | | | |
| | m²) | | | | | |
| | Number of | 4 | 3 | 1 | 0 | 0 |
| | conductive | | | | | |
| | foreign | | | | | |
| | matters | | | | | |
| | having size | | | | | |
| | of 50 μm or | | | | | |
| | more | | | | | |
| | in surface | | | | | |
| | (number/ | | | | | |
| | m²) | | | | | |
| | Appearance | ⊙ | ⊙ | ⊙ | ⊙ | ⊙ |
| Stacking | Yield of | ⊙ | ⊙ | ⊙ | ⊙ | ⊙ |
| of copper | bonding | | | | | |
| foil and | Adhesion | 1.1 | 1.1 | 1.2 | 1.1 | 1 |
| film | strength to | | | | | |
| | copper foil | | | | | |
| | (N/mm) | | | | | |

The results of Comparative Examples 1 to 6 are shown in Table 3.

TABLE 3

| | | Comparative | Comparative | Comparative | Comparative | Comparative | Comparative |
|---|---|---|---|---|---|---|---|
| | | Example 1 | Example 2 | Example 3 | Example 4 | Example 5 | Example 6 |
| Film | Unstable terminal group | 507 | 507 | 507 | 324 | 324 | 324 |
| | Number per 1 × 10⁶ per carbon | | | | | | |
| | atoms in main chain of fluororesin | | | | | | |
| | Presence or absence of | absence | absence | absence | absence | absence | absence |
| | ultrasonic cleaning of filter | | | | | | |
| | Presence or absence of sintering | absence | absence | absence | presence | presence | presence |
| | treatment of filter | | | | | | |
| | Average film thickness of surface | 50 | 25 | 12.5 | 50 | 25 | 12.5 |
| | (um) | | | | | | |
| | Number of carbide having length | 32 | 31 | 30 | 41 | 39 | 40 |
| | of 50 μm or more | | | | | | |
| | (number/m²) | | | | | | |
| | Number of nickel having length of | 33 | 32 | 30 | 20 | 18 | 19 |
| | 50 μm or more | | | | | | |
| | (number/m²) | | | | | | |
| | Number of conductive foreign | 68 | 68 | 66 | 63 | 63 | 64 |
| | matters having size of 50 μm or | | | | | | |
| | more in surface | | | | | | |
| | (number/m²) | | | | | | |
| | Appearance | x | x | x | x | x | x |
| Stacking of | Yield of bonding | x | x | x | x | x | x |
| copper foil | Adhesion strength | 1.1 | 1.2 | 1.1 | 1.1 | 1 | 1 |
| and film | to copper foil | | | | | | |
| | (N/mm) | | | | | | |

From the results of Tables 2 and 3, the fluororesin film of the present disclosure has a reduced number of conductive foreign matters per square meter and can be expected as a material for a circuit board that has excellent appearance and less defects in bonding to metal foil.

### INDUSTRIAL APPLICABILITY

The fluororesin film of the present disclosure can be suitably used for a metal-clad laminated board for a circuit board.

1. A fluororesin film that is a film comprising a fluororesin,
wherein the number of conductive foreign matters that are present in the film and have a length of 50 μm or more in a flow direction or a width direction of the film is less than 60/square meter.

2. The fluororesin film according to claim 1, wherein the number of unstable functional groups of the fluororesin is less than 350 per 1×10⁶ carbon atoms in a main chain of the fluororesin.

3. The fluororesin film according to claim 1, wherein the fluororesin is a tetrafluoroethylene/perfluoro (alkyl vinyl ether) copolymer or a tetrafluoroethylene/hexafluoropropylene copolymer.

4. The fluororesin film according to claim 1, wherein a melt flow rate of the fluororesin at 372° C. and a load of 49 N is 0.1 to 50 g/10 minutes.

5. The fluororesin film according to claim 1, wherein the fluororesin film has an area of one square meter or more.

6. The fluororesin film according to claim 1, wherein the conductive foreign matters comprise nickel and/or carbide.

7. The fluororesin film according to claim 1, wherein the fluororesin film has an adhesion strength of 0.8 N/mm or more when bonded to metal foil having a surface roughness Rz of 1.5 μm or less.

8. The fluororesin film according to claim 1, wherein the fluororesin film is used for a metal-clad laminated board.
